(19) United States
(12) Patent Application Publication
(10) Pub. No.: US 2019/0130552 A1
(43) Pub. Date: May 2, 2019

(54) METHODS OF INSPECTING DEFECT AND METHODS OF FABRICATING A SEMICONDUCTOR DEVICE USING THE SAME

(71) Applicant: Samsung Electronics Co., Ltd., Suwon-si (KR)

(72) Inventors: Young-hoon Sohn, Incheon (KR); Sung-yoon Ryu, Suwon-si (KR); Yu-sin Yang, Seoul (KR)

(73) Assignee: Samsung Electronics Co., Ltd., Suwon-si (KR)

(21) Appl. No.: 15/984,774

(22) Filed: May 21, 2018

(30) Foreign Application Priority Data
Oct. 30, 2017 (KR) 10-2017-0142568

(51) Int. Cl. G06T 7/00; G01N 21/95; H01L 21/66; H01L 21/027; G03F 1/38; G03F 1/36

(52) U.S. Cl. CPC G06T 7/001; G01N 21/9501; H01L 22/24; G06T 2207/30148; G03F 1/38; G03F 1/36; H01L 21/0273

(57) ABSTRACT

A method of inspecting a defect including dividing a semiconductor substrate including the plurality of dies into a plurality of inspection regions, each of the plurality of inspection regions having at least one die, the semiconductor substrate including a pattern provided thereon, obtaining an optical image from each of the plurality of inspection regions, obtaining differential images between a reference region, and comparison regions, the reference region being one of the plurality of inspection regions, the comparison regions being regions other than the reference region from among the plurality of inspection regions, determining an abnormal pixel by performing a signal analysis with respect to respective signal intensities of same-location pixels in the differential images, and designating one or more possible weak patterns by comparing the abnormal pixel with a design pattern may be provided.

### CROSS-REFERENCE TO RELATED APPLICATION

This application claims priority under 35 U.S.C. § 119 to Korean Patent Application No. 10-2017-0142568, filed on Oct. 30, 2017, in the Korean Intellectual Property Office, the disclosure of which is incorporated herein in its entirety by reference.

### BACKGROUND

The inventive concepts relate to methods of inspecting a defect and/or methods of fabricating a semiconductor device by using the methods of inspecting a defect, and more particularly, to methods of inspecting a weak pattern that may induce a defect and/or methods of fabricating a semiconductor device by using the method of inspecting the weak pattern.

Electronic devices are becoming more and more miniaturized in association with the rapid development of electronic industries and demands of users. Therefore, a semiconductor device with a high degree of integration is demanded to be used in electronic devices, and design rules for the structures of semiconductor devices are becoming finer. As a result, the standards for inspection of defects, which induce failure of semiconductor devices, are becoming higher, and optical technologies for detecting defects are reaching their limits.

### SUMMARY

The inventive concepts provide a method of inspecting a weak pattern that may induce a defect and a method of fabricating a semiconductor device by using the method of inspecting the weak pattern.

According to an aspect of the inventive concepts, a method of inspecting a defect includes dividing a semiconductor substrate including the plurality of dies into a plurality of inspection regions, each of the plurality of inspection regions having at least one die, the semiconductor substrate including a pattern provided thereon, obtaining an optical image from each of the plurality of inspection regions, obtaining differential images between a reference region, and comparison regions, the reference region being one of the plurality of inspection regions, the comparison regions being regions other than the reference region from among the plurality of inspection regions, determining an abnormal pixel by performing a signal analysis with respect to respective signal intensities of same-location pixels in the differential images, and designating one or more possible weak patterns by comparing the abnormal pixel with a design pattern may be provided.

According to another aspect of the inventive concepts, a method of fabricating a semiconductor device includes providing a plurality of semiconductor substrates, forming a pattern, the pattern defining a plurality of dies on each of the plurality of semiconductor substrate, dividing one of the plurality of semiconductor substrates into a plurality of inspection regions, each of the plurality of inspection regions having at least one die, obtaining differential images between a reference region and comparison regions, the reference region being one of the plurality of inspection regions, of the comparison regions being regions other than the reference region from among the plurality of inspection regions, determining an abnormal pixel by performing a signal analysis with respect to respective signal intensities of same-location pixels in the differential images, designating one or more weak patterns by comparing the abnormal pixel with a design pattern, and enhancing the weak pattern.

According to another aspect of the inventive concepts, a method of inspecting a defect includes obtaining an optical image from each of a plurality of inspection regions on a semiconductor substrate, the semiconductor substrate including a pattern, the pattern defining a plurality of dies on the semiconductor substrate by using a mask, the mask having a size of a field, a field corresponding to a group of two or more dies, each of a plurality of inspection regions corresponding to the field in terms of size, comparing a reference region, with each of comparison regions, the reference region being one from among the plurality of inspection regions and disposed at a central region of the semiconductor substrate, the comparison regions being regions other than the reference region from among the plurality of inspection regions, obtaining inter-region differential images between the reference region and respective ones of the comparison regions, determining abnormal pixels by performing a signal analysis with respect to signal intensities according to locations of same-location pixels in the inter-region differential images, designating one or more possible weak patterns by comparing the abnormal pixels with a design pattern, and designating a repeated pattern group obtained by categorizing and analyzing the designated one or more possible weak patterns.

### BRIEF DESCRIPTION OF THE DRAWINGS

Example embodiments of the inventive concepts will be more clearly understood from the following detailed description taken in conjunction with the accompanying drawings in which:

FIGS. 1A and 1B are plan view diagrams showing a structure of a semiconductor substrate used in methods of inspecting a defect and/or methods of fabricating a semiconductor device using the methods of inspecting a defect, according to some example embodiments;

FIG. 2 is a schematic diagram for describing a method of inspecting a defect according to an example embodiment;

FIG. 3 is a graph for describing defects that may be detected by a method of inspecting a defect according to an example embodiment;

FIGS. 4A, 4B, and 4C are graphs for describing a method of inspecting a defect according to an example embodiments;

FIGS. 5A, 5B, 5C, and 6A, and 6B are graphs for describing a method of inspecting a defect according to some example embodiments;

FIG. 7A is an inter-region differential image obtained according to a method of inspecting a defect according to a comparative example using conventional methods, and FIG. 7B is an inter-region differential image obtained according to a method of inspecting a defect according to an example embodiment;

FIG. 8 is a flowchart showing a method of inspecting a defect and fabricating a semiconductor device according to an example embodiment;

FIG. 9 is a schematic diagram for describing a method of analyzing a repeated pattern group in a method of inspecting a defect according to an example embodiment;

FIG. 10 is a flowchart showing a method of fabricating a semiconductor device using a method of inspecting a defect according to an example embodiment;

FIG. 11 is a flowchart showing a method of fabricating a semiconductor device using a method of inspecting a defect according to example embodiments; and

FIG. 12 is a flowchart showing a method of fabricating a semiconductor device by using a method of inspecting a defect according to example embodiments.

### DETAILED DESCRIPTION

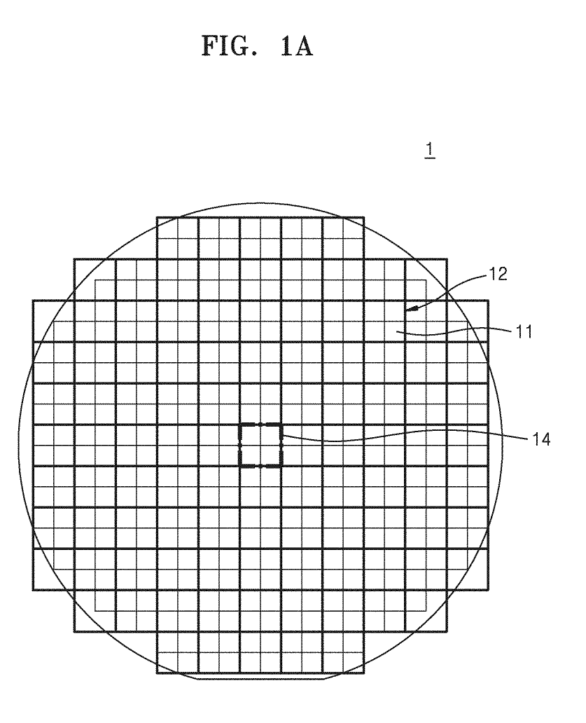

FIGS. 1A and 1B are plan view diagrams showing a structure of a semiconductor substrate used in a method of inspecting a defect and/or a method of fabricating a semiconductor device using the method of inspecting a defect, according to some example embodiments.

Referring to FIG. 1A, a plurality of dies (chips) 11, which are independently operational units, are formed on a semiconductor substrate 1 by forming a certain pattern on the semiconductor substrate 1. The semiconductor substrate 1 may include, for example, silicon (Si) (e.g., crystalline Si, polycrystalline Si, or amorphous Si). Alternatively, the semiconductor substrate 1 may include a semiconductor element, such as germanium (Ge), and at least one semiconductor compound selected from among silicon germanium (SiGe), silicon carbide (SiC), gallium arsenide (GaAs), indium arsenide (InAs), and indium phosphide (InP). Alternatively, the semiconductor substrate 1 may have a silicon-on-insulator (SOI) structure. For example, the semiconductor substrate 1 may include a buried oxide (BOX) layer. The semiconductor substrate 1 may include a conductive region, e.g., a well doped with an impurity or a structure doped with an impurity.

An exposure process is performed by dividing the entire semiconductor substrate 1 into a plurality of sections and using a mask (or reticle) with respect to the plurality of dies 11 as one field 12, which is a repeating unit. The exposure process may be performed, for example, by using DUV light, EUV light, or E-beam. The exposure process may be performed, for example, by a scanner, a stepper, or a step-and-scan tool. The one field 12 may include the plurality of dies 11. In a photo process of each step, the plurality of dies 11 may be formed on the semiconductor substrate 1 via a single shot using a mask having formed thereon such as the field 12. For example, the one field 12 may include from 2 to 8 dies 11. In other words, in the present specification, the field 12 may correspond to a collection of dies on a mask and, at the same time, correspond to a collection of dies 11 formed on a wafer by using a mask.

In the semiconductor substrate 1 having a pattern formed thereon, defects, such as particles and voids, may occur. Particularly, a defective pattern may be repeatedly detected by inspection equipment while a semiconductor fabricating process is being performed. The reason thereof may be repetitive use of a mask having a defect in a photolithography process.

Referring to FIG. 1B, a plurality of dies 11a are formed on a semiconductor substrate 1a. An exposure process is performed by dividing the entire semiconductor substrate 1a into a plurality of sections and using a mask (or reticle) with respect to one die 11a as one field 12, which is a repeating unit. In a photo process of each step, the one die 11a may be formed on the semiconductor substrate 1a via a single shot using a mask having formed thereon such as the field 12a.

Referring to FIGS. 1A and 1B, one field 12 or 12a may include the plurality of dies 11 or the one die 11a according to the area of the die 11 or 11a to be formed.

One of a plurality of fields 12 or 12a constituting the semiconductor substrate 1 or 1a may be designated as a reference region 14 or 14a for defect inspection. For example, from among the plurality of fields 12 or 12a, reference region 14 or 14a may be disposed at the center portion of the semiconductor substrate 1 or 1a or at a location near the center portion.

According to some embodiments, even when the field 12 includes the plurality of dies 11 as shown in FIG. 1A, one of the plurality of dies 11 may be designated as a reference region, and thus defect inspection may be performed similarly as in the case shown in FIG. 1B where the field 12a includes the one die 11a.

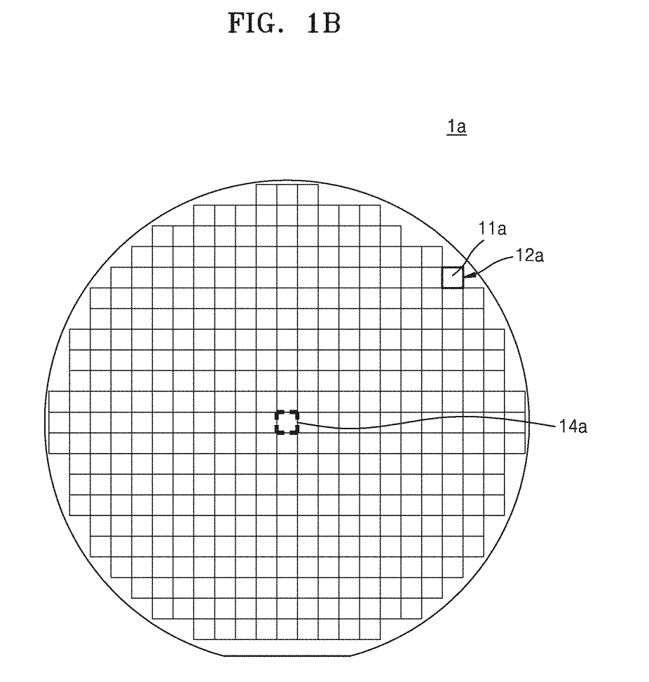

FIG. 2 is a schematic diagram for describing a method of inspecting a defect according to example embodiments.

Referring to FIG. 2, a method of inspecting a defect may be performed by comparing a reference region with a comparison region. For example, the method of inspecting a defect may be performed by obtaining a differential image between an optical image obtained in the reference region and an optical image obtained in the comparison region. The comparison region refers to a field or a die to be compared with the reference region, and the reference region and the comparison region will be both referred to as inspection regions.

The differential image between the optical image of the reference region and the optical image of the comparison region may be obtained by comparing pixels Px included in the reference region with pixels Px included in the comparison region, the pixels Px being at the same corresponding locations in the reference region and the comparison region. In the present specification, the pixels Px at the same corresponding locations in the comparison region and the reference region may be referred to as same-location pixels. A pixel Px may be a unit pixel constituting an obtained optical image.

In conventional methods of inspecting a defect, regions adjacent to each other are compared to each other, and whether there is a defect is determined by comparing one region with regions at both sides of the region. In other words, in the conventional methods of inspecting a defect, whether there is a defect is determined by comparing three regions. In the conventional methods of inspecting a defect, each region may be designated as a reference region, and any or all regions adjacent to each region may be designated as comparison regions. Furthermore, each of reference regions and comparison regions may be included in one field, one die, or a portion of a die. A reference region and a comparison region may be any regions as long as the regions include patterns corresponding to each other.

Referring to FIGS. 1A and 1B, in some methods of inspecting a defect according to some example embodiments, one of the plurality of fields 12 or 12a constituting the semiconductor substrate 1 or 1a may be designated as the reference region 14 or 14a. The reference region 14 or 14a may be one of the plurality of fields 12 or 12a that is disposed at the center or central region of the semiconductor substrate 1 or 1a.

From among the plurality of fields 12 or 12a, fields other than the field designated as the reference region 14 or 14a may be designated as comparison regions.

A method of inspecting a defect according to an example embodiments may be performed by obtaining a differential image between an optical image obtained in the one field designated as the reference region 14 or 14a from among the plurality of fields 12 or 12a and optical images obtained in the comparison regions, which are regions other than the field designated as the reference region 14 or 14a.

According to some example embodiments, the reference region and the comparison regions may be one from among the plurality of dies 11 and 11a and the remaining dies 11 or 11a, respectively.

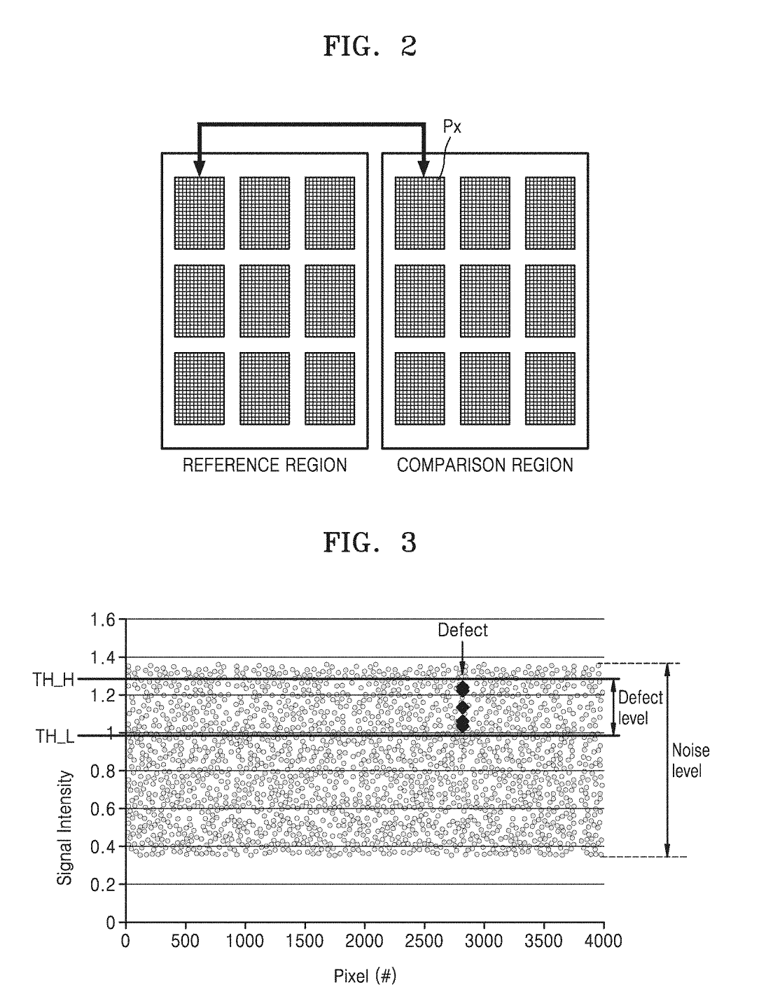

FIG. 3 is a graph for describing defects that may be detected by a method of inspecting a defect according to an example embodiment.

Referring to FIGS. 2 and 3 together, signal intensities obtained by comparing a same-location pixel Px in optical images obtained in the reference region and the comparison regions, respectively, may have noises distributed within a noise level, which is an interval between constant signal intensity values. A defect may have a signal intensity distributed between a low threshold TH_L and a high threshold TH_H of signal intensity obtained by comparing the same-location pixel Px in optical images obtained in the reference region and the comparison regions, respectively.

Because a signal intensity having a value greater than a noise level is defined as a threshold in the conventional methods of inspecting a defect, a pixel Px having a signal intensity greater than the signal intensity of noise may be detected as a defect. Therefore, if the signal intensity of a defect has a value within a noise level, the conventional methods may not be able to detect the defect.

On the other hand, in methods of inspecting a defect according to some example embodiments, defects having a value of a signal intensity within a noise level may be detected by comparing a defect level, which is an interval between signal intensity values of pixels having defects, with the width of each noise level or comparing a tendency of signal intensities of the pixels having defects with a tendency of signal intensities of pixels having no defect.

Signal intensities obtained by comparing the same-location pixel Px in the reference region with the comparison regions may be distributed within a noise level. Because noises commonly appear within a certain range in a random manner, signal intensities obtained by comparing the same-location pixels Px may be distributed within a range of a noise level that has a substantially uniform interval.

However, when the signal intensities obtained by comparing particular pixels Px are distributed within a level having an interval different from that of the noise level in which the other pixels Px are distributed, the particular pixels Px may have a defect. A pixel Px that may have a defect may be referred to as an abnormal pixel, and the remaining pixels Px may be referred to as normal pixels. Similarly, a signal obtained from an abnormal pixel may be referred to as an abnormal signal, and a signal obtained from a normal pixel may be referred to as a normal signal.

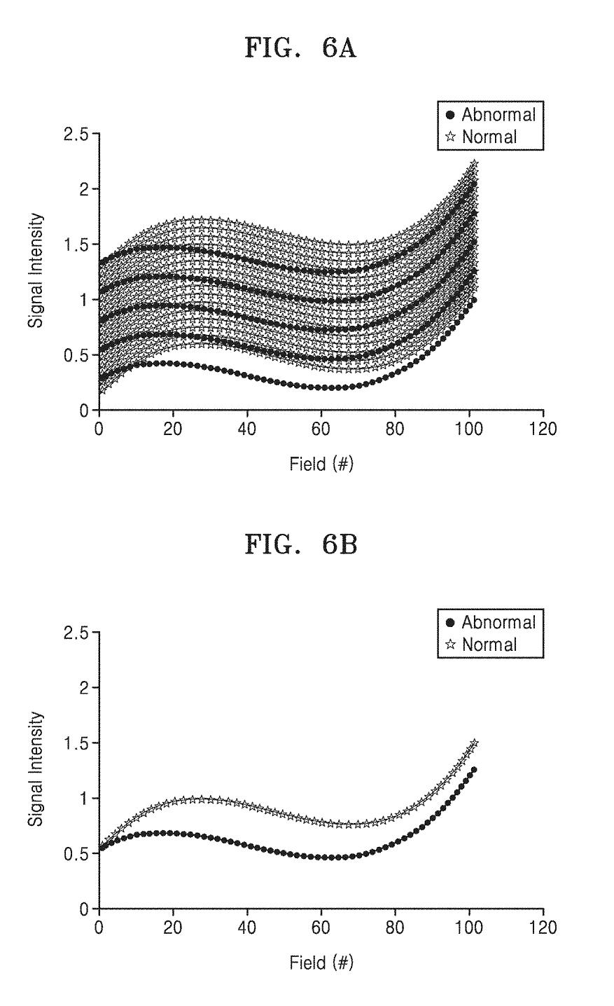

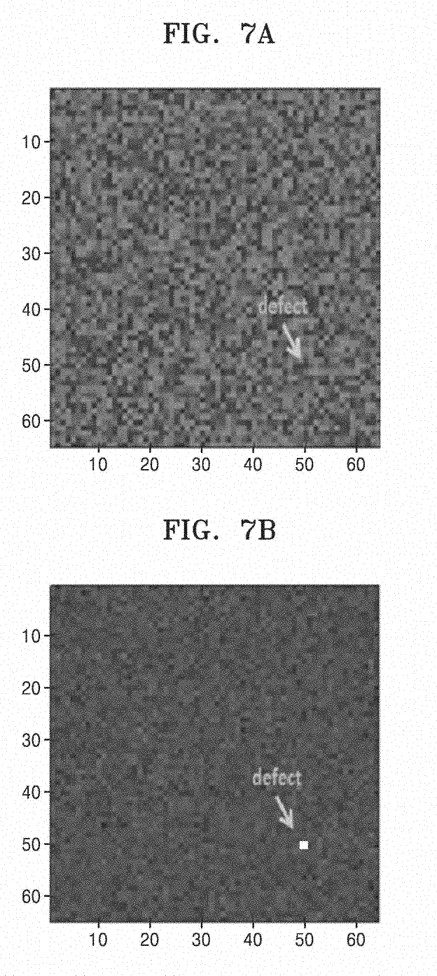

Here, the meaning that the corresponding particular pixel Px may not have a defect or may have a defect will be described below in detail with reference to FIGS. 8 and 9.

In some example embodiments, a possibility of having a defect may be determined by comparing a degree of scattering of signal intensities obtained by particular same-location pixels Px in the reference region with the comparison regions. For example, when the degree of scattering of comparison signal intensities obtained from a relatively large number of pixels Px differs from the degree of scattering of comparison signal intensities obtained from a relatively small number of pixels Px, the relatively small number of pixels Px may have a defect.

In some example embodiments, a possibility of having a defect may be determined by comparing changing tendencies of signal intensities obtained by comparing particular same-location pixels in a reference region with each comparison region. For example, when the changing tendencies of comparison signal intensities obtained from a relatively large number of pixels Px differs from the changing tendencies of comparison signal intensities obtained from a relatively small number of pixels Px, the relatively small number of pixels Px may have a defect.

For example, the degree of scattering of the comparison signal intensities obtained from the relatively large number of pixels Px may be referred to as a noise level, whereas the degree of scattering of the comparison signal intensities obtained from the relatively small number of pixels Px may be referred to as a defect level. Therefore, pixels Px having a signal intensity distributed within the defect level may have a defect.

Although the defect level and the noise level are indicated by ranges in FIG. 3, the inventive concepts are not limited thereto. The defect level and the noise level may be indicated by quartile deviation, mean deviation, standard deviation, Gini's mean difference, etc. For example, the defect level may have a value less than that of the noise level.

According to some example embodiments, the defect level may have a value greater than that of the noise level. However, in such cases, a defect may be detected even by using conventional methods of inspecting a defect (e.g., by designating a signal intensity having a value greater than the noise level as a reference point).

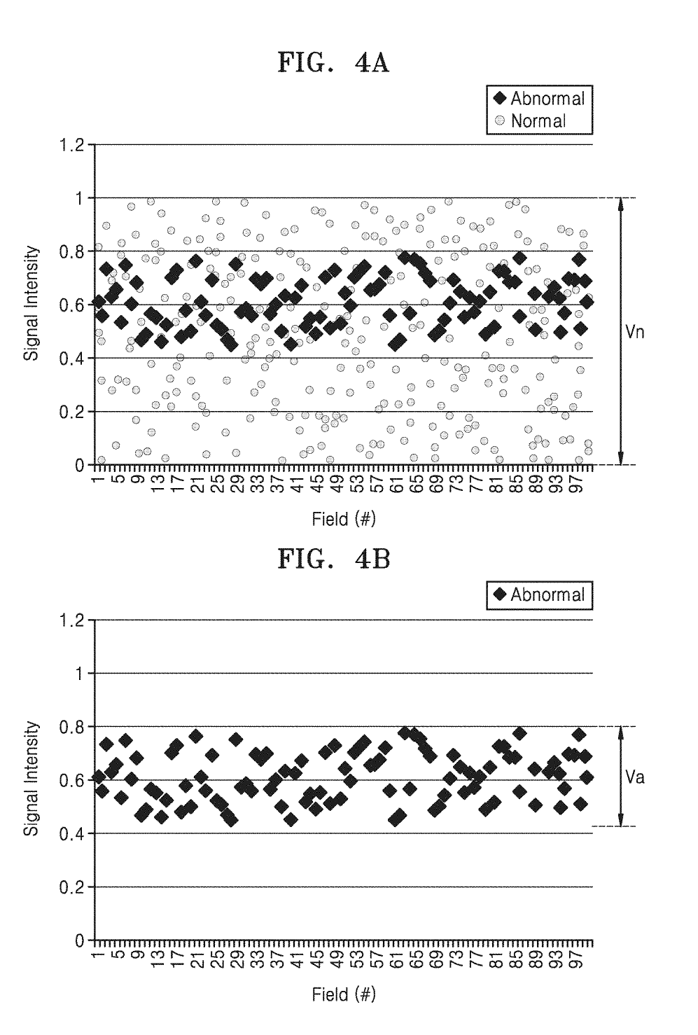

FIGS. 4A through 4C are graphs for describing a method of inspecting a defect according to example embodiments. FIG. 3 is a graph in which pixel numbers are arranged on the X axis, whereas FIGS. 4A through 4C are graphs in which field numbers are arranged on the X axis. Here, the pixel number and the field number are numbers arbitrarily assigned to distinguish pixels and fields different from one another, respectively, and sequences of the pixel numbers and the field numbers sequence has no specific meaning (e.g., order) unless specifically defined.

Referring to FIG. 2 and FIG. 4A together, signal intensities obtained by comparing same-location pixels Px in the reference region with each of the comparison regions are shown. For example, all the signal intensities obtained at abnormal pixels and normal pixels may have values within a noise level Vn.

Referring to FIGS. 2, 4B, and 4C, the signal intensities obtained at the abnormal pixels among the signal intensities obtained by comparing the same-location pixels Px in the reference region with each of the comparison regions may be located within a level having a relatively small width, that is, a defect level Va. On the other hand, the signal intensities obtained at the normal pixels among the signal intensities obtained by comparing the same-location pixels Px in the reference region with each of the comparison regions may be located within a level having a relatively large width, that is, the noise level Vn. The defect level Va may have a relatively smaller value than the noise level Vn.

Referring to FIGS. 2 and 4A through 4C, the signal intensities obtained at the same-location pixels Px from among the signal intensity obtained by comparing the same-location pixel Px in the reference region with each of the comparison region may be isolated to determine a tendency of the signal intensities.

In the methods of inspecting a defect according to some example embodiments, signals obtained by comparing the same-location pixels Px in the reference region with each of the comparison regions may be space-resolved inspection signals each including spatial information (e.g., information regarding locations of fields (dies) and locations of pixels Px).

The pixels Px having signal intensities distributed within the defect level Va, which has a relatively small width than the noise level Vn as shown in FIG. 4B, may be determined as abnormal pixels, whereas the pixels Px having signal intensities distributed within the noise level Vn, which has a relatively large width than the defect level Va as shown in FIG. 4C, may be determined as normal pixels. Here, the defect level Va and the noise level Vn do not have desired (or alternatively, pre-set) widths, and may be obtained by isolating and analyzing signal intensities obtained at the same-location pixels Px.

When the signal intensities of particular same-location pixels Px within a field (die) exhibits a specific tendency different from those of the other same-location pixels Px throughout a semiconductor substrate, a pattern formed in a corresponding region may be a pattern that may have defects, which may have been caused by a mask pattern formed on a mask (reticle).

Although FIG. 4B shows that the defect level Va has a certain range, the inventive concepts are not limited thereto. For example, same-location pixels Px may exhibit different defect levels if the defect levels of the respective same-location pixels PX have widths or center or mean values different from one another.

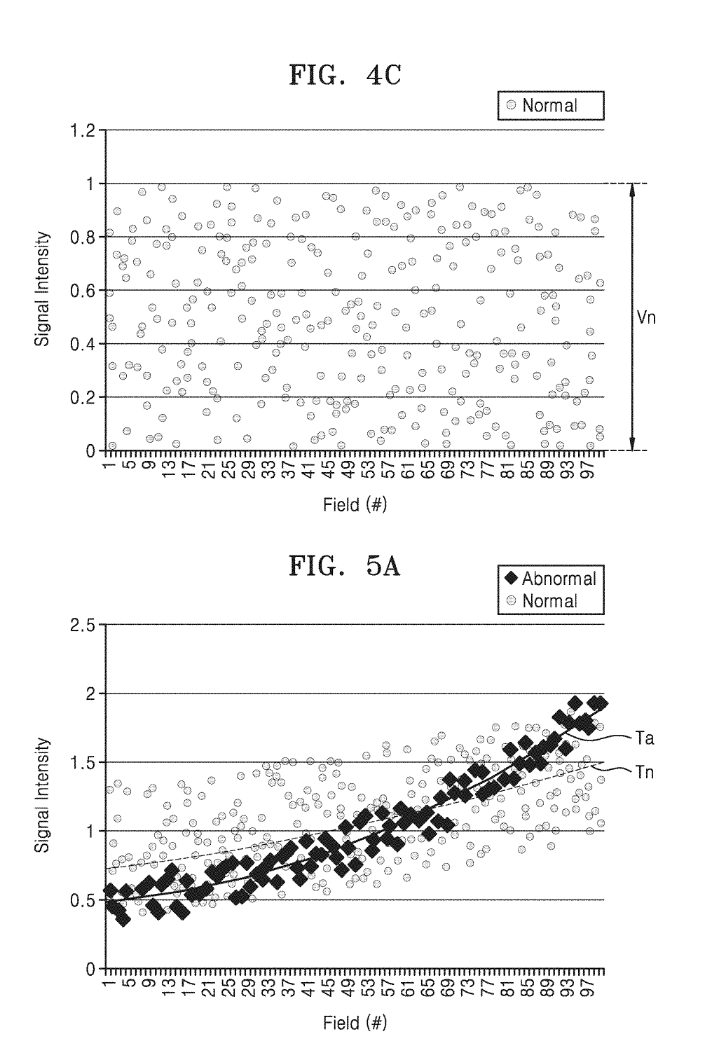

FIGS. 5A and 6B are graphs for describing a method of inspecting a defect according to some example embodiments.

Referring to FIGS. 2 and 5A together, signal intensities obtained by comparing the same-location pixels Px in the reference region with each of the comparison region are shown. For example, the signal intensities obtained at the abnormal pixels and the normal pixels may have values indicating a noise tendency Tn and a defect tendency Ta, respectively.

Referring to FIGS. 2, 5B, and 5C, the signal intensities obtained at the abnormal pixels from among the signal intensities obtained by comparing the same-location pixels Px in the reference region with each of the comparison region may exhibit the defect tendency Ta corresponding to relatively large increases, whereas the signal intensities obtained at the normal pixels from among the signal intensities obtained by comparing the same-location pixels Px in the reference region with each of the comparison region may exhibit the noise tendency Tn corresponding to relatively small increases.

Referring to FIGS. 2 and 5A through 5C, signal intensities obtained at the same-location pixels Px may be isolated from the signal intensities obtained by comparing the same-location pixels Px in the reference region with each of the comparison regions to determine the tendency of the signal intensities.

As shown in FIG. 5B, the pixels Px having signal intensities exhibiting the defect tendency Ta corresponding to relatively large increases may be determined as abnormal pixels, whereas the pixels Px having signal intensities exhibiting the noise tendency Tn corresponding to relatively small increases may be determined as normal pixels. Here, the defect tendency Ta and the noise tendency Tn do not have desired (or alternatively, pre-set) tendencies, and may be obtained by isolating and analyzing the signal intensities obtained at the same-location pixels Px.

According to these example embodiments, the abnormal pixels and the normal pixels are not determined based on the number of pixels associated with the increasing tendency of the signal intensities. For example, even when the number of pixels corresponding to relatively large increases of signal intensity is less than the number of pixels corresponding to relatively small increases of signal intensity, the pixels corresponding to relatively large increases of signal intensity can be determined as abnormal pixels. On the other hand, when the number of pixels corresponding to relatively large increases of signal intensity is greater than the number of pixels corresponding to relatively small increases of signal intensity, the pixels corresponding to relatively small increases of signal intensity can be determined as abnormal pixels.

Furthermore, the signal intensity of each of the same-location pixels Px may not only exhibit an increasing tendency, but also exhibit a decreasing tendency or both an increasing tendency and a decreasing tendency together.

After analyzing the tendency of change of the signal intensity of each of the same-location pixels Px, a relatively small number of same-location pixels Px exhibiting a tendency of change of signal intensity different from a tendency of change of signal intensity of a relatively large number of same-location pixels Px may be determined as abnormal pixels.

According to some example embodiments, a degree of scattering of signal intensities obtained at abnormal pixels exhibiting the defect tendency Ta may have a value less than that of a degree of scattering of signal intensities obtained at normal pixels exhibiting the noise tendency Tn.

Referring to FIGS. 2 and 5A through 5C, signal intensities obtained at the same-location pixels Px may be isolated among the signal intensities obtained by comparing the same-location pixels Px in the reference region with each of the comparison regions to determine the tendency of the signal intensities.

The pixels Px having signal intensities exhibiting the defect tendency Ta within a level having a relatively small width as shown in FIG. 5B may be determined as abnormal pixels, whereas the pixels Px having signal intensities exhibiting the noise tendency Tn within a level having a relatively large width as shown in FIG. 5C may be determined as normal pixels. Here, the defect tendency Ta and the noise tendency Tn do not have desired (or alternatively, pre-set) tendencies, and may be obtained by isolating and analyzing the signal intensities obtained at the same-location pixels Px.

Depending on processes performed prior to formation of a pattern, a semiconductor substrate may have different film thicknesses depending on locations, different cumulative stress depending on films or an influence of an underlying structure. An interrupting defect, such as a discoloration, may occur due to spatial gradient characteristics of the semiconductor substrate. Because such an interrupting defect appears largely based on differences between locations of the semiconductor substrate, conventional methods of inspecting a defect may minimize such interrupting defects by comparing a region with adjacent regions. The conventional methods of inspecting a defect, however, may not be able to detect an actual defect caused by the spatial gradient characteristics of a semiconductor substrate.

According to methods of inspecting a defect according to some example embodiments, a difference between tendencies of signal intensities may be analyzed by comparing tendencies of signal intensities appearing between locations of a semiconductor substrate, that is, fields, and thus detection of such an actual defect becomes possible.

Referring to FIGS. 1A, 1B, and 5A through 5C together, relatively small field numbers may indicate the center or central portions of the semiconductor substrates 1 and 1a, whereas relatively large field numbers may indicate edge portions of the semiconductor substrates 1 and 1a. However, it is merely an example. For example, the relatively small field numbers may indicate the edge portions of the semiconductor substrates 1 and 1a, whereas the relatively large field numbers may indicate the center or central portions of the semiconductor substrates 1 and 1a.

For example, the overall signal intensities may tend to increase in a direction from the center or central portions to the edge portions depending on locations of the fields. Such a tendency of signal intensities may be an interrupting defect that does not cause an actual failure. However, because signal intensities obtained at abnormal pixels have a tendency of change different from that of signal intensities obtained at normal pixels, the abnormal pixels may have an actual defect rather than an interrupting defect.

When the signal intensities of particular same-location pixels Px in a field (die) exhibit an extraordinary tendency of change different from that of the other same-location pixels Px depending on locations of a semiconductor substrate, a pattern formed in the corresponding region may be a weak pattern that may have an actual defect irrelevant to the spatial gradient characteristics of the semiconductor substrate or an actual defect due to amplification of the spatial gradient characteristics of the semiconductor substrate rather than merely an interrupting defect due to the spatial gradient characteristics of the semiconductor substrate.

A tendency of change of signal intensity obtained at each of the same-location pixels Px may be represented by fitting a change of signal intensity of each field to a two-dimensional function. However, the inventive concepts are not limited thereto. For example, the tendency of change of signal intensity obtained at each of the same-location pixels Px may be represented by fitting a change of signal intensity of each field to a one-dimensional function or a function having three or higher dimensions.

FIG. 6A shows a tendency of change of signal intensity obtained at each of the same-location pixels by fitting the same. A relatively small number of same-location pixels Px exhibiting a tendency of change of signal intensity different from a tendency of change of signal intensities of normal pixels, which are a relatively large number of same-location pixels Px, may be determined as abnormal pixels.

Pixels in a field may have different signal intensities due to an influence of an underlying structure, and/or a difference between patterns being formed. Even when signal intensities obtained at pixels of a same field have values different from one another, a relatively large number of pixels with similar tendencies of change of signal intensities may be normal pixels. Furthermore, a relatively small number of pixels with tendencies of change of signal intensities different from those of the normal pixels may be abnormal pixels.

Although FIG. 6A shows that tendencies of change of signal intensities of abnormal pixels are similar to one another, the inventive concepts are not limited thereto. For example, some of abnormal pixels may have tendencies of change of signal intensities different from those of normal pixels, wherein some of the abnormal pixels may have tendencies of change of signal intensities different from those of the other some of the abnormal pixels.

Referring to FIG. 6B, a tendency of change of signal intensity obtained at the reference region is compared with a tendency of change of signal intensity obtained at each of the comparison regions. After fitting the tendency of change of signal intensity obtained at the same-location pixels, a representative tendency of change of signal intensity may be extracted to determine normal pixels and abnormal pixels.

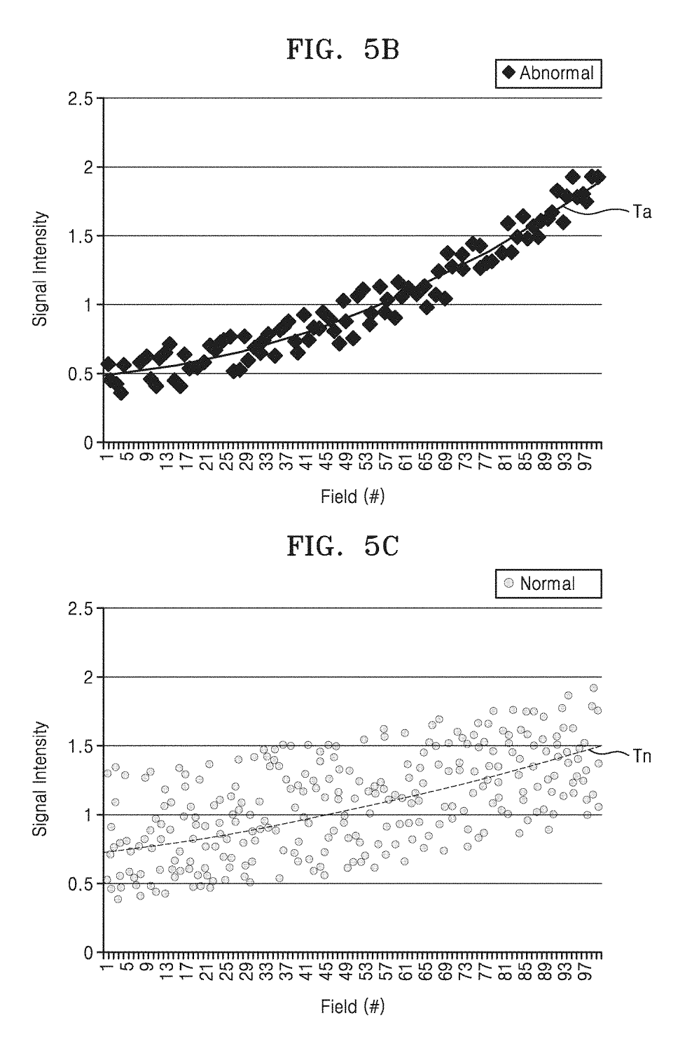

FIG. 7A is an inter-region differential image obtained according to a method of inspecting a defect according to a comparative example using conventional methods, and FIG. 7B is an inter-region differential image obtained according to a method of inspecting a defect according to an example embodiment.

Referring to FIG. 7A, a defective pixel may not be distinguished from noise in the inter-region differential image obtained according to the method of inspecting a defect according to the comparative example.

Referring to FIG. 7B, an abnormal pixel may be clearly distinguished by imaging tendencies of signal intensities of same-location pixels in the inter-region differential image obtained according to the method of inspecting a defect according to an example embodiment. For example, FIG. 7B may be an image showing intervals between signal intensities of same-location pixels or an image showing a coefficient variation obtained by fitting signal intensities.

FIG. 8 is a flowchart showing a method of inspecting a defect and fabricating a semiconductor device according to an example embodiment.

Referring to FIG. 8, a semiconductor substrate is provided (operation S100). The semiconductor substrate may be the semiconductor substrate 1 or la as shown in FIG. 1A or 1B. The semiconductor substrate may be, for example, a bare semiconductor wafer or a focus exposure matrix (FEM) wafer. The semiconductor substrate may be a semiconductor wafer on which a semiconductor fabricating process is performed, that is, a bare semiconductor wafer having formed thereon at least one material layer and/or at least one pattern.

A pattern constituting a plurality of dies is formed on the provided semiconductor substrate (operation S200). The pattern may be, for example, a photoresist pattern. In order to form the pattern constituting a plurality of dies on the semiconductor substrate, an exposure process may be performed by using a mask having a field including one die or a plurality of dies.

In some example embodiments, the pattern may be a pattern obtained as a result of performing an etching process using a photoresist pattern as an etch mask, for example. In order to form the pattern on the semiconductor substrate, a photoresist pattern may be formed by performing an exposure process using a mask, and then an etching process using the photoresist pattern as an etch mask may be performed. The etching process may be, for example, a dry etching process or a wet etching process, but is not limited thereto.

After the pattern is formed on the semiconductor substrate, defect inspection is performed (operation S300). In order to perform the defect inspection, an inspection region is first defined in the semiconductor substrate (operation S310). The inspection region may be set by dividing the semiconductor substrate into a plurality of sections. Each inspection region may be a region formed via a single shot using a mask. For example, when the mask has a field including a group of a plurality of dies, each inspection region may be a field including a group of a plurality of dies.

According to some example embodiments, each inspection region may be an individual die on the semiconductor substrate. For example, when a mask has a field including one die, each inspection region may be one die. In some example embodiments, even when the mask has a field including a group of a plurality of dies, each inspection region may be a die.

At least one inspection region from among the defined inspection regions is designated as a reference region (operation S312). For example, the reference region may be one from among the inspection regions (e.g., fields or dies) that is located at the center portion of the semiconductor substrate or a location adjacent to the center portion of the semiconductor substrate. From among the defined inspection regions, inspection regions other than the reference region may be comparison regions.

When defining an inspection region, an unit pixel for obtaining an optical image via an inspection region may be defined together, and the inspection region may include a plurality of pixels. Inspection regions and the plurality of pixels associated therewith may be defined to have spatial information (operation S314). The spatial information may include location information of the respective inspection regions and information regarding respective locations of the plurality of pixels in the inspection regions.

An optical image of each inspection region is obtained (operation S320). The optical image may be obtained, for example, by irradiating each inspection region with UV light, DUV light, EUV light, or E-beam. Each of the inspection regions including a reference region and comparison regions may include the same number of same-sized pixels. The size and the number of pixels constituting an optical image obtained in each inspection region may vary depending on the wavelength of light irradiated during the process of obtaining the optical image. The obtained optical image may be, for example, a gray level image in which the signal intensity of each pixel has a value from 0 to 255.

The optical images obtained in the respective comparison regions are compared with the optical image obtained in the reference region to obtain inter-region differential images for the respective comparison regions (operation S330). The number of inter-region differential images that may be obtained may be equal to the number of the comparison regions. An inter-region differential image may be obtained based on a difference between an optical image obtained in each comparison region and the signal intensities of same-location pixels in the optical image obtained in the reference region. In order to obtain the inter-region differential image, information regarding location of respective pixels in spatial information may be used. Furthermore, because the inter-region differential images are generated with respect to the respective comparison regions, each of the inter-region differential images may have location information regarding the respective comparison regions. The location information regarding the respective comparison regions may be information regarding distances between the locations of the respective comparison regions to the reference region on the semiconductor substrate.

Signal analysis is performed on the inter-region differential image (operation S340). The signal analysis for the inter-region differential image may be performed based on information regarding locations of respective regions by taking the signal intensities of the same-location pixels in the inter-region differential images into account. In a result of the signal analysis regarding the inter-region differential image, as described above with reference to FIGS. 3 through 6B, pixels exhibiting widths or tendencies of change of signal intensities different from that of the majority of pixels may be determined as abnormal pixels having abnormal signals. An abnormal signal may be determined by using a signal discrimination algorithm. An abnormal signal may indicate that a pattern formed at a location including the corresponding pixel may have a defect, but does not indicate that a pattern formed at a location including the corresponding pixel has a defect for sure.

Locations of abnormal pixels having abnormal signals are compared with a design pattern, and possible weak patterns are selected (operation S350). For example, the design pattern may be a Graphic Database System II (GDSII). A possible weak pattern may be the design pattern formed at a location corresponding to an abnormal pixel having an abnormal signal.

In some example embodiments, a design pattern may be different from an actually formed pattern, e.g., a photoresist pattern or an etch pattern. The design pattern may be a result of performing optical proximity correction (OPC) in consideration of an aerial image, an image-in-resist, a latent image in resist obtained via an exposure, a latent image obtained via post-exposure bake (PEB), a developed resist image, or a post-etch image.

In the process of selecting possible weak patterns, not only a design pattern corresponding to the location of an abnormal pixel may be selected, but also a design pattern related to the location of the abnormal pixel may be selected. For example, when a design pattern includes a portion that is less than a corresponding portion of an actually formed pattern due to an OPC, there may be no design pattern corresponding to the location of an abnormal pixel in the pattern design. In such cases, the possible weak pattern may be a design pattern formed at a location corresponding to an abnormal pixel having an abnormal signal and a location adjacent thereto.

After categorizing the possible weak patterns, a repeated pattern group is analyzed (operation S360). The repeated pattern group refers to a same pattern from among the selected weak patterns by being rotated, symmetrical, enlarged, or reduced. A method of analyzing a repeated pattern group will be described below with reference to FIG. 9.

A weak pattern is designated based on a result of the analysis of the repeated pattern group (operation S370). Repeated patterns occupying a certain proportion (or more) of the repeated pattern group or corresponding to a certain number (or greater) of repeated patterns in the repeated pattern group may be designated as the weak pattern.

The weak pattern designated during the defect inspection as described above is enhanced (operation S400). Methods of improving a weak pattern may include, for example, mask redesign, photo process rework, or etch recipe modification.

According to some example embodiments, a possible weak pattern may be immediately designated as a weak pattern without performing an analysis on a repeated pattern group. For example, when the number of possible weak patterns is relatively small or it is determined by using a review scanning electron microscope (SEM) that most of the possible weak patterns are of similar types, the possible weak patterns may be immediately designated as weak patterns without performing an analysis on a repeated pattern group.

FIG. 9 is a schematic diagram for describing a method of analyzing a repeated pattern group in a method of inspecting a defect according to an example embodiment.

Referring to FIG. 9, possible weak patterns P1, P2, P3, and, which correspond to a same pattern by being rotated, symmetrical, enlarged, and reduced from among possible weak patterns selected in operation S350 of FIG. 8, are categorized into one repeated pattern group PG.

Although FIG. 9 shows the possible weak patterns P1, P2, P3, and P4 that may correspond to a same pattern by being rotated or symmetrical are categorized into one repeated pattern group PG, the inventive concepts are not limited thereto. Possible weak patterns that may correspond to a same pattern through symmetric enlargement or reduction of the size or asymmetric enlargement or reduction of the size, may be categorized into one repeated pattern group PG because in OPC, a design pattern may be formed via symmetric enlargement or reduction of the size or asymmetric enlargement or reduction considering influence of an adjacent pattern.

According to some example embodiments, possible weak patterns corresponding to a same pattern (e.g., circles or squares) without being rotated or symmetrical may be grouped into a repeated pattern group as-is. Even in this case, possible weak patterns corresponding to a same pattern via symmetrical or asymmetrical enlargement or reduction of the size of a circle or a square pattern may be classified into one repeated pattern group.

According to some example embodiments, a repeated pattern group may be categorized in consideration of scanning directions in an exposure process. In other words, in case of considering scanning direction in an exposure process, only possible weak patterns having abnormal pixels having abnormal signals in a same scanning direction may be categorized into a repeated pattern group and possible weak patterns having abnormal pixels having abnormal signals in a different scanning direction may not be categorized into the repeated pattern group.

Each of the patterns P1, P2, P3, and P4 may include a plurality of pixels. The number of possible weak patterns may be less than the number of abnormal pixels.

The weak pattern enhancement described above in the operation S400 of FIG. 8 may be performed in consideration of locations of abnormal pixels in a weak pattern. Thus, when an abnormal pixel is detected at a particular location in a weak pattern, the location where an abnormal pixel is formed in the weak pattern may be weak. Therefore, mask re-design, photo process rework, or etch recipe modification may be performed with respect to the corresponding location.

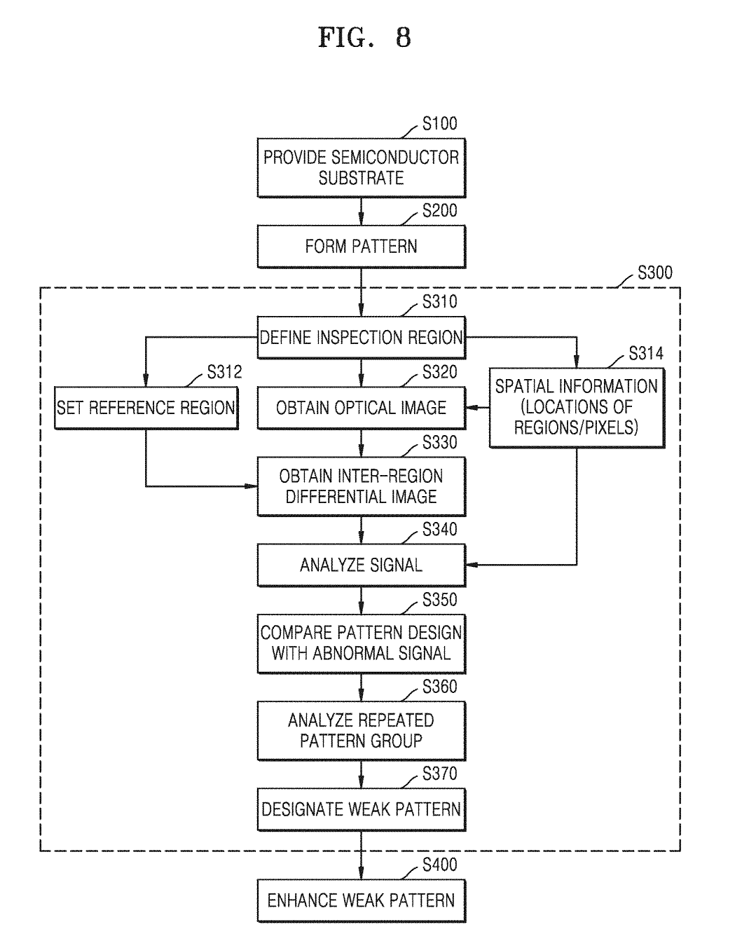

FIG. 10 is a flowchart showing a method of fabricating a semiconductor device using a method of inspecting a defect according to an example embodiment.

Referring to FIG. 10, a semiconductor substrate is provided (operation S102), and a pattern is formed on the provided semiconductor substrate (operation S202). The pattern may be, for example, a photoresist pattern or a pattern obtained as a result of performing an etching process by using a photoresist pattern as an etch mask. Next, a weak pattern inspection is performed (operation S302). The weak pattern inspection may be performed in the same manner as the defect inspection described above with reference to FIG. 8. For example, for the weak pattern inspection, a plurality of dies are formed by forming a pattern on the semiconductor substrate, and a field, which includes a group of a plurality of dies, or each die is defined as an inspection region. Next, optical images of respective inspection regions are obtained. After obtaining inter-region differential images by comparing an optical image of a reference region, which is one of the designated inspection regions, with the optical images of the other inspection regions, possible weak patterns are selected via a signal analysis with respect to the inter-region differential images that is obtained in consideration of signal intensities of same-location pixels based on locations of the respective inspection regions, and a weak pattern may be designated by categorizing the possible weak patterns and analyzing a repeated pattern group.

After the weak pattern inspection, a weak pattern is determined (operation S412). If a designated weak pattern is found as a result of the weak pattern inspection, a mask is redesigned (operation S422). The mask redesign may include OPC in consideration of the designated weak pattern.

The result of the weak pattern inspection indicates that there is no designated weak pattern, the semiconductor device fabricating process is continued (operation S502) to form a semiconductor device on the semiconductor substrate.

The semiconductor device may be, for example, a central processing unit (CPU), a microprocessor unit (MPU), a graphics processing unit (GPU), an application processor (AP), a volatile semiconductor memory device, such as a dynamic random access memory (DRAM) and a static random access memory (SRAM), or a non-volatile semiconductor memory device, such as a flash memory, a phase-change random access memory (PRAM), a magneto-resistive random access memory (MRAM), a ferroelectric random access memory (FeRAM), or a resistive random access memory (RRAM). The flash memory may be a vertical NAND (V-NAND) flash memory, for example.

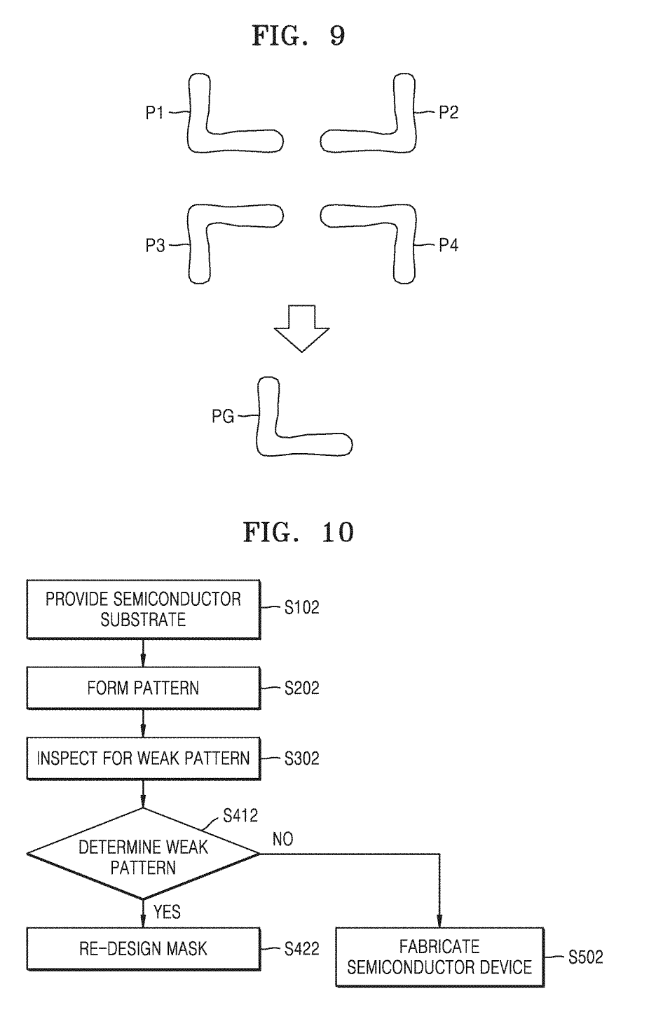

FIG. 11 is a flowchart showing a method of fabricating a semiconductor device using a method of inspecting a defect according to an example embodiment.

Referring to FIG. 11, a semiconductor substrate is provided (operation S104), and a photoresist pattern is formed on the provided semiconductor substrate (operation S204). The photoresist pattern may be formed, for example, via an exposure process performed by using DUV light, EUV light, or E-beam. Next, a weak pattern inspection is performed (operation S304). The weak pattern inspection may be performed in the same manner as the defect inspection described above with reference to FIG. 8. For example, for the weak pattern inspection, a plurality of dies are formed by forming a pattern on the semiconductor substrate, and a field, which includes a group of a plurality of dies, or each die is defined as an inspection region. Next, optical images of respective inspection regions are obtained. After obtaining inter-region differential images by comparing an optical image of a reference region, which is one of the designated inspection regions, with the optical images of the other inspection regions, possible weak patterns are selected via a signal analysis with respect to the inter-region differential images that is obtained in consideration of signal intensities of same-location pixels based on locations of the respective inspection regions, and a weak pattern may be designated by categorizing the possible weak patterns and analyzing a repeated pattern group.

After the weak pattern inspection, a weak pattern is determined (operation S414). If a result of the weak pattern inspection indicates that there is a designated weak pattern, a photolithography process is re-worked (operation S424). For example, the photolithography process may be re-worked by removing the formed photoresist pattern via an ashing process or a stripping process, modifying the recipe of the photolithography process, and forming a new photoresist pattern. The modification of the recipe of the photolithography process may include an exposure recipe change, such as a focusing degree change or an exposure time change, a post-exposure bake (PEB) recipe change, or a developing recipe change.

Next, a weak pattern inspection may be performed again on the new photoresist pattern (operation S304).

If no designated weak pattern is found as a result of the weak pattern inspection, an etching process is performed by using the photoresist pattern as an etch mask (operation S504), and the semiconductor device fabricating process is continued to form a semiconductor device on the semiconductor substrate.

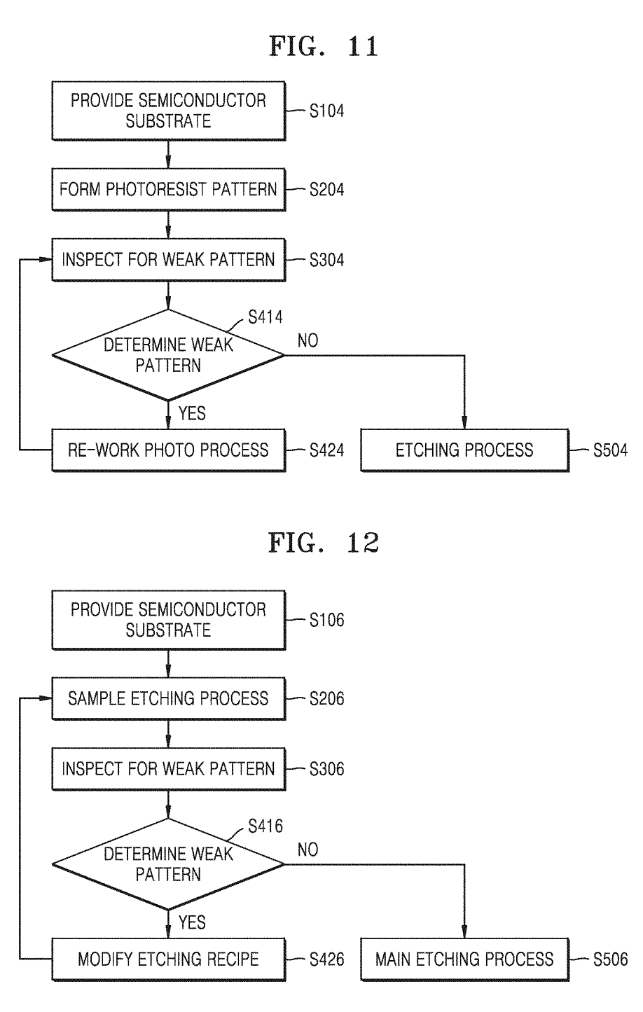

FIG. 12 is a flowchart showing a method of fabricating a semiconductor device by using a method of inspecting a defect according to an example embodiment.

Referring to FIG. 12, a semiconductor substrate is provided (operation S106), and a pattern is formed by performing a sample etching process on the provided semiconductor substrate (operation S206). For example, the pattern may be a pattern obtained as a result of performing an etching process by using a photoresist pattern as an etch mask. The sample etching process refers to a process for forming a photoresist pattern on each of a plurality of provided semiconductor substrates and performing an etching process on some of the plurality of semiconductor substrates having formed thereon photoresist patterns by using photoresist patterns as etch masks. For example, after photoresist patterns are formed on the semiconductor substrates, an etching process may be performed on one or two of the semiconductor substrate by using the photoresist patterns as etch masks.

A weak pattern inspection is performed with respect to a semiconductor substrate on which a pattern is formed by performing the sample etching process (operation S306). The weak pattern inspection may be performed in the same manner as the defect inspection described above with reference to FIG. 8. For example, for the weak pattern inspection, a plurality of dies are formed by forming a pattern on the semiconductor substrate via the sample etching process, and a field, which includes a group of a plurality of dies, or each die is defined as an inspection region. Next, optical images of respective inspection regions are obtained. After obtaining inter-region differential images by comparing an optical image of a reference region, which is one of the designated inspection regions, with the optical images of the other inspection regions, possible weak patterns are selected via a signal analysis with respect to the inter-region differential images that is obtained in consideration of signal intensities of same-location pixels based on locations of the respective inspection regions, and a weak pattern may be designated by categorizing the possible weak patterns and analyzing a repeated pattern group.

After the weak pattern inspection, a weak pattern is determined (operation S416). If a designated weak pattern is found as a result of the weak pattern inspection, the etching recipe is modified and a sample etching process is performed again (operation S206). The re-performance of the sample etching process refers to an etching process with respect to one or two other of the semiconductor substrates, on which the previous sample etching process is not performed, from among semiconductor substrates having formed thereon photoresist patterns, by using the photoresist patterns as etch masks. Next, a weak pattern inspection may be performed again with respect to a pattern formed on the one or two semiconductor substrate as a result of performing the sample etching process again (operation S306).

if no designated weak pattern is found as a result of the weak pattern inspection, a main etching process for performing an etching process with respect to the remaining semiconductor substrates on which the sample etching process has not been performed is performed by using the photoresist patterns as etch masks (operation S506). Next, the semiconductor device fabricating process is continued to form a semiconductor device on the semiconductor substrate.

By using a method of inspecting a defect according to some example embodiments, a defect that is difficult to be detected because its signal intensity is located within a noise level, or defects that are difficult to be detected due to an existence of an interrupting defect associated with spatial gradient characteristics of a semiconductor substrate, may be detected by comparing tendencies of signal intensity according to locations of the semiconductor substrate. Here, a tendency of signal intensity may include a degree of scattering of the signal intensities according to locations of same-location pixels or a tendency of change of the signal intensities according to locations.

Furthermore, a weak pattern is designated by selecting possible weak patterns from abnormal pixels and analyzing a repeated pattern group categorizing the possible weak patterns, instead of directly determining a defect by using an abnormal pixel having an abnormal signal. Thus, weak pattern which may cause a defect may be detected relatively accurately.

While the inventive concepts have been particularly shown and described with reference to some example embodiments thereof, it will be understood that various changes in form and details may be made therein without departing from the spirit and scope of the following claims.

What is claimed is:

1. A method of inspecting a defect, the method comprising:
dividing a semiconductor substrate including a plurality of dies into a plurality of inspection regions, each of the plurality of inspection regions having at least one die, the semiconductor substrate including a pattern provided thereon;
obtaining an optical image from each of the plurality of inspection regions;
obtaining differential images between a reference region, and comparison regions, the reference region being one of the plurality of inspection regions, the comparison regions being regions other than the reference region from among the plurality of inspection regions;
determining an abnormal pixel by performing a signal analysis with respect to respective signal intensities of same-location pixels in the differential images; and
designating one or more possible weak patterns by comparing the abnormal pixel with a design pattern.

2. The method of claim 1, wherein
the pattern is a photoresist pattern formed by using a mask, the mask having a field accommodating a certain number of the plurality of dies therein, and
each of the plurality of inspection regions has a size corresponding to the field.

3. The method of claim 1, wherein
the pattern is formed by performing an etching process using a photoresist pattern as an etch mask, and
the photoresist pattern is formed by using a mask, the mask having a field accommodating a certain number of the plurality of dies therein.

4. The method of claim 1, wherein the reference region is a region located at a central portion of the semiconductor substrate from among the plurality of inspection regions.

5. The method of claim 1, wherein the determining an abnormal pixel includes comparing at least one of degrees of scatterings corresponding to locations of the same-location pixels, respectively, or changing tendencies of signal intensities corresponding to locations of the same-location pixels, respectively, to one another.

6. The method of claim 1, wherein the determining an abnormal pixel includes determining pixels, from among the same-location pixels, showing degrees of scattering of signal intensities each less than a threshold degree as abnormal pixels.

7. The method of claim 1, wherein the determining an abnormal pixel includes determining pixels having tendencies of changes of signal intensities different from tendencies of changes of signal intensities of a majority of same-location pixels as abnormal pixels.

8. The method of claim 7, wherein the determining an abnormal pixel includes fitting the tendencies of changes of signal intensities of the same-location pixels according to respective locations to a 2-dimensional function.

9. The method of claim 1, further comprising:
determining a repeated pattern group by categorizing the one or more possible weak patterns; and
designating the repeated pattern group as a weak pattern.

10. The method of claim 9, wherein the repeated pattern group corresponds to a same pattern from among the designated one or more possible weak patterns, the same pattern including one or more patterns having a same shape by being rotated, symmetrical, enlarged, or reduced.

11. A method of fabricating a semiconductor device, the method comprising:
providing a plurality of semiconductor substrates;
forming a pattern, the pattern defining a plurality of dies on each of the plurality of semiconductor substrate;
dividing one of the plurality of semiconductor substrates into a plurality of inspection regions, each of the plurality of inspection regions having at least one die;
obtaining optical images from the plurality of inspection regions, respectively;
obtaining differential images between a reference region and comparison regions, the reference region being one of the plurality of inspection regions, the comparison regions being regions other than the reference region from among the plurality of inspection regions;
determining an abnormal pixel by performing a signal analysis with respect to respective signal intensities of same-location pixels in the differential images;
designating one or more weak patterns by comparing the abnormal pixel with a design pattern; and
enhancing the weak pattern.

12. The method of claim 11, wherein
the forming a pattern comprises forming of a photoresist pattern by using a mask, and
the enhancing the weak pattern comprises removing the photoresist pattern and forming a new photoresist pattern.

13. The method of claim 11, wherein
the forming a pattern comprises forming a photoresist pattern on each of the plurality of semiconductor substrates by using a mask, and performing a sample etching process by performing an etching process on some of the plurality of semiconductor substrates having formed thereon the photoresist patterns by using the photoresist patterns as an etch mask; and
the enhancing the weak pattern comprises performing an etching process on other some of the plurality of semiconductor substrates, on which the photoresist patterns have been formed by using the photoresist patterns as an etch mask.

14. The method of claim 11, wherein the enhancing the weak pattern comprises revising a mask.

15. The method of claim 11, wherein
the reference region is a region located at a central portion of the semiconductor substrate from among the plurality of inspection regions; and,
the determining an abnormal pixel comprises determining the abnormal pixel by performing a signal analysis with respect to signal intensities according to a location of each of the comparison regions including the same-location pixels.

16. The method of claim 11, wherein the designating one or more weak patterns comprises:
determining a repeated pattern group by analyzing and categorizing and the one or more weak patterns; and
designating the repeated pattern group as a weak pattern by comparing the abnormal pixel to the design pattern.

17. A method of inspecting a defect, the method comprising:
obtaining an optical image from each of a plurality of inspection regions on a semiconductor substrate, the semiconductor substrate including a pattern, the pattern defining a plurality of dies on the semiconductor substrate by using a mask, the mask having a size of a field, a field corresponding to a group of two or more dies, each of a plurality of inspection regions corresponding to the field in terms of size;
comparing a reference region, with each of a plurality of comparison regions, the reference region being one from among the plurality of inspection regions and disposed at a central region of the semiconductor substrate, the comparison regions being regions other than the reference region from among the plurality of inspection regions;
obtaining inter-region differential images between the reference region and respective ones of the comparison regions;
determining abnormal pixels by performing a signal analysis with respect to signal intensities according to locations of same-location pixels in the inter-region differential images;
designating one or more possible weak patterns by comparing the abnormal pixels with a design pattern; and
designating a repeated pattern group obtained by categorizing and analyzing the designated one or more possible weak patterns.

18. The method of claim 17, wherein
the repeated pattern group corresponds to a same pattern from among the determined one or more possible weak patterns by being rotated, symmetrical, enlarged, or reduced, and
the method further comprises designating a weak pattern by analyzing the repeated pattern group, the designating a weak pattern including designating repeated pattern occupying at least a certain proportion of the repeated pattern group or corresponding to at least a certain number of repeated patterns in the repeated pattern group.

19. The method of claim 17, wherein the pattern defining the plurality of dies is a photoresist pattern.

20. The method of claim 17, wherein the pattern defining the plurality of dies is formed by performing an etching process using a photoresist pattern as an etch mask, the photoresist pattern is formed by using the mask.
